(19) United States
(12) Patent Application Publication
(10) Pub. No.: US 2022/0314048 A1
(43) Pub. Date: Oct. 6, 2022

(54) BATTERY OPERATED FIRE EXTINGUISHER

(71) Applicant: FIRE BOT INC., Lorton, VA (US)

(72) Inventor: Mark Steven BALDINO, Lorton, VA (US)

(21) Appl. No.: 17/608,598

(22) PCT Filed: May 1, 2020
(86) PCT No.: PCT/US2020/030952

§ 371 Date: Nov. 3, 2021

Related U.S. Application Data
(60) Provisional application No. 62/842,756, filed on May 3, 2019.

(51) Int. Cl. A62C 25/00; G01R 31/371

(52) U.S. Cl. CPC A62C 25/00; G01R 31/371

(57) ABSTRACT

The present disclosure describes a handheld fire extinguisher comprising a housing, a container disposed within the housing, where the container is configured to store a fire suppressant material, and a nozzle. The handheld fire extinguisher can also include a pump in fluid communication with the container and the nozzle, where the pump is configured to pump the fire suppressant from the container to the nozzle, a battery configured to selectively power the pump, and a controller in signal communication with the battery and configured to control operation of the battery.

### CROSS-REFERENCE TO RELATED APPLICATIONS

This application is the National Stage of International Patent Application No. PCT/US2020/030952, filed May 1, 2020, which claims the benefit of U.S. Provisional Application No. 62/842,756, filed May 3, 2019, the disclosures of which are incorporated herein by reference in their entireties.

### TECHNICAL FIELD

This application generally relates to fire extinguishers, and, more particularly, to handheld fire extinguishers utilizing battery-powered pumps.

### BACKGROUND

Fire has a large economic impact. Fires impact insurance rates through structure damage and damage claims. More importantly, they also cause death and injury in the structures they impact. Managing fires and reducing their damage requires many devices and having an effective handheld extinguisher is one of the necessary tools. Fire extinguishers work by reducing the temperature of the material under fire, removing access to oxygen by shielding material under liquid or creating a film on top the material. It is well known that one should not put water on an oil fire. That means that one must match fire suppressant to the fire conditions, by incorporating mechanisms that enable remote monitoring and diagnostics of the fire extinguisher.

Many conventional handheld fire extinguishers use pressurized containers containing dry chemicals or liquid fire suppressants. Such handheld fire extinguishers require inspection at defined intervals to confirm they have not lost their pressurization, and therefore their effectiveness. This required inspection requires the expenditure of money and/or time, thus significantly increasing the true cost of a pressurized fire extinguisher. As a result, there is a need for a handheld fire extinguisher that reduces the true cost of the fire extinguisher through increasing ease of conducting inspections and decreasing required inspection frequency.

The information included in this Background section of the specification, including any references cited herein and any description or discussion thereof, is included for technical reference purposes only and is not to be regarded subject matter by which the scope of the invention is to be bound.

### SUMMARY

An embodiment of the present disclosure is a handheld fire extinguisher comprising a housing, a container disposed within the housing, where the container is configured to store a fire suppressant material, and a nozzle. The handheld fire extinguisher can also include a pump in fluid communication with the container and the nozzle, where the pump is configured to pump the fire suppressant from the container to the nozzle, a battery configured to selectively power the pump, and a controller in signal communication with the battery and configured to control operation of the battery.

This summary is not intended to identify key features or essential features of the claimed subject matter, nor is it intended to be used to limit the scope of the claimed subject matter. A more extensive presentation of features, details, utilities, and advantages of the present invention is provided in the following written description of various embodiments of the invention, illustrated in the accompanying drawings, and defined in the appended claims.

### BRIEF DESCRIPTION OF THE DRAWINGS

The foregoing summary, as well as the following detailed description, will be better understood when read in conjunction with the appended drawing. The drawing shows an illustrative embodiment of the disclosure. It should be understood, however, that the application is not limited to the precise arrangements and instrumentalities shown.

FIG. 1 illustrates a cross-sectional view of a handheld fire extinguisher according to an aspect of the present disclosure.

### DETAILED DESCRIPTION OF ILLUSTRATIVE EMBODIMENTS

Certain terminology used in this description is for convenience only and is not limiting. The words “top”, “bottom”, “above,” and “below” designate directions in the drawings to which reference is made. The term “substantially” is intended to mean considerable in extent or largely but not necessarily wholly that which is specified. All ranges disclosed herein are inclusive of the recited endpoint and independently combinable (for example, the range of “from 2 grams to 10 grams” is inclusive of the endpoints, 2 grams and 10 grams, and all the intermediate values). The terminology includes the above-listed words, derivatives thereof and words of similar import.

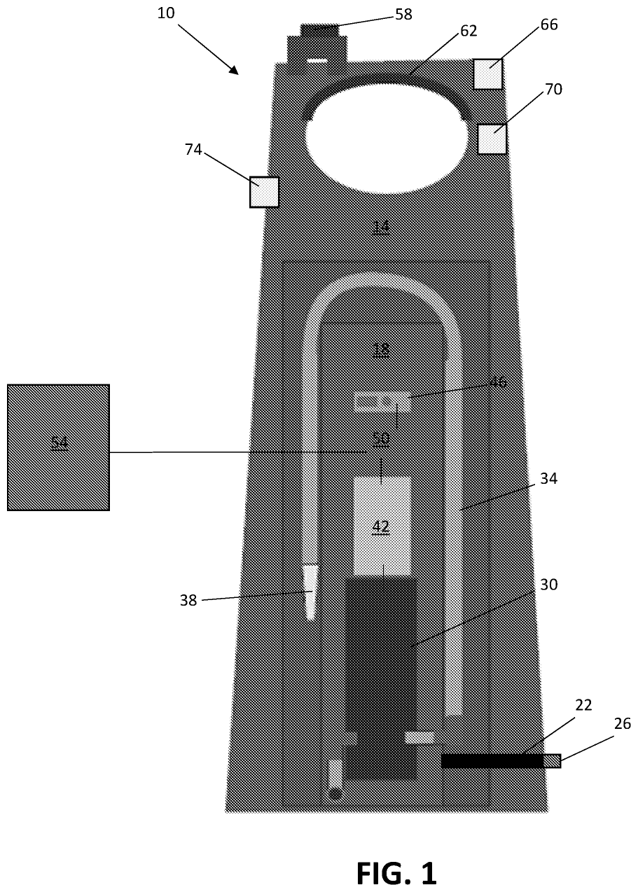

Referring to FIG. 1, a handheld fire extinguisher 10 according to an embodiment of the present disclosure will be described. The handheld fire extinguisher 10 may also be referred to as an electronic fire fighting extinguisher (EFFE). The handheld fire extinguisher 10 can be configured to be manually held by an operator and actuated so as to extinguish a fire. The handheld fire extinguisher 10 can comprise a housing 14 configured to house components of the handheld fire extinguisher 10. The housing 14 can define a substantially hollow shell, and can be comprised of plastic, metal, or any other rigid material capable of being formed into a hollow housing and resistant to heat. The housing 14 can include a mount that allows the handheld fire extinguisher 10 to be releasably mounted to a wall or other environmental feature.

The handheld fire extinguisher 10 can include a container 18 configured to be disposed within the housing 14. The container 18 can be configured to store the fire suppressant material. In one embodiment, the container 18 is a plastic housing that can contain from sixteen ounces to five gallons or more of a fire suppressant material, which would provide the handheld fire extinguisher with sufficient fire suppressant material for operation of thirty seconds to five minutes or more. The container 18 can be a flexible pouch comprising thin, flexible, plastic film to hold the fire suppressant material. The container 18 can also comprise multiple separate containers configured to store a single type of fire suppressant material or multiple types of fire suppressant material to be combined during operation.

In some embodiments, the container 18 is refillable. In such embodiments, the handheld fire extinguisher 10 can include a fill port 22 that extends from the container 18 through the housing 14. The fill port 22 can be configured to allow an operator to refill the container 18 with additional fire suppressant material, or alternatively pump the fire suppressant material out of the container 18. The fill port 22 can be sealed by a fill cap 26 releasably coupled to the fill port 22 or the housing 14 through snap-fit engagement, threaded engagement, etc. The container 18 can also be replaceable. In some embodiments, the container 18 may be replaced with a quick connect connector.

The handheld fire extinguisher 10 can further include a pump 30 in fluid communication with the container 18. The pump 30 can be configured to pump the fire suppressant material from the container 18. The pump 30 can be a diaphragm pump, gear pump, screw pump, progressing cavity pump, roots-type pump, plunger pump, triplex-style plunger pump, compressed-air-powered double-diaphragm pump, rope pump, impulse pump, hydraulic ram pump, radial-flow pump, axial-flow pump, mixed-flow pump, eductor-jet pump, or gravity pump. The pump 30 can be configured to create 50 to 100 PSI of pressure, as well as a flow of 2.0 to 5.0 liters per minute, or any necessary number of liters per minute, of fire suppressant material from the container 18. The pump 30 can be configured to pump the fire suppressant material from the container 18, and through a hose 34 to a nozzle 38. The hose 34 can comprise a flexible plastic or rubber hose, and can have a diameter that depends upon the type of nozzle 38 utilized, size of the container 18, type of fire suppressant material utilized, etc. Additionally, the hose 34 can be chemical and fire resistant. Though one pump, container, and nozzle combination is shown, in other embodiments the handheld fire extinguisher 10 can utilize multiple pump, container, and nozzle combinations for additional fire suppressant functionality or for redundancy.

Quick connectors may be used to attach the hosing to the pump and to split the hosing into two different leads. For example, when there are two nozzles, one for each nozzle. The quick connectors allow a quick and secure connection to tubing for ease in configuration and replacements of components such as suppressant bags, etc.

The nozzle 38 can comprise various opening sizes. Spray nozzle 38 can be threaded with the hose 34 and/or the housing 14 to allow substitution of nozzles having different size aperture jets to allow dispersal of different liquids at variable pressures. Opening size of the spray nozzle 38 may vary from 0.05 mm to 0.30 mm, though other sizes are contemplated. In some cases, other variations of the opening and nozzle design may be used in specific conditions. In one embodiment, multiple nozzles are used each for a set of different fire suppressant material. The shape of nozzle array may vary in form and physical geometric shape, and one to multiple nozzles may be used. In another embodiment, the nozzle 38 is adjustable so as to produce a plurality of spray patterns of the fire suppressant material. To be effective and efficient the fire suppressant material can be emitted in the smallest droplet size possible yet large enough not to be affected by drift, the displacement of fire suppressant by heat rise or wind so it does not land on the fire. Volume control of the fire suppressant material from the nozzle 38 can be controlled by inserting washers of various diameters into the nozzle 38, causing restricted flow. Volume and spray pattern can be regulated by the selecting nozzle openings, where the smaller the diameter of the openings, the less volume of fire suppressant material is emitted from the nozzle. The stronger the pump 30 used, the more pressure is applied to the fire suppressant material and the more volume is emitted. The handheld fire extinguisher 10 further include a plurality of interchangeable nozzles 38 that can be interchanged as desired by the operator.

The handheld fire extinguisher 10 can further include a battery 42 configured to selectively power the pump 30. The battery 42 can be a low voltage (for example, as low as 1.5V) Li-ion, alkaline, Ni-Cad, or Gel battery. The battery 42 can provide AC power through an inverter to an AC powered pump or DC power to a DC powered pump 30. DC batteries can be primary or secondary power sources and may be rechargeable, allowing the operation of the handheld fire extinguisher 10 after an extended period where electricity is not available. In some embodiments, the pump 30 may have a 12V or 24V DC motor. The handheld fire extinguisher 10 can include a port 46 attached to the housing and electrically connected to the battery 42, where the battery 42 is configured to be charged through the port 46. The handheld fire extinguisher 10 can be recharged periodically with a plug-in low voltage transformer. Power can be supplied to the battery 42 by connecting the port 46 to a transformer or a hardwired transformer wired directly to power. In some embodiments, the battery 42 is replaceable. In other embodiments, the battery 42 could be used separately or as a back up, in case of a power outage, to a direct power source such as an AC-DC transformer power system. The transformer may be a plug-in transformer or built into the fire extinguisher. A capacitor can be used in certain embodiments to store electrical energy to power the pump 30 and a controller 50.

To control the pump 30 and/or the battery 42, the handheld fire extinguisher 10 can include a controller 50 in signal communication with the battery 42 and configured to control operation of the battery 42. The controller 50 can comprise any suitable computing device configured to host a software application for monitoring and controlling various operations of the handheld fire extinguisher 10 as described herein. The controller 50 is the central control for the handheld fire extinguisher 10 and supports real-time and non-real-time control, management and communication software. The controller 50 can initiate input to activate the input of the motor 30 for receiving power from the battery 42, utilize a timer to pulse the motor 30 if desired, measure the voltage of the battery 42, output for a piezoelectric device, etc.

The controller 50 can be in wired and/or wireless signal communication with an operation device 54, such that the controller 50 is configured to send signals to the operation device 54 that are indicative of an operational condition of the battery 42 and/or the pump 30. The operation device 54 can be located remotely from the handheld fire extinguisher 10. The controller 50 is also configured to receive signals from the operation device 54 that are indicative of instructions regarding operation of the battery 42 and/or the pump 30. The operation device 54 can be a computer, tablet, mobile phone, etc. The operation device 54 can be utilized to monitor the handheld fire extinguisher 10, or the operation device 54 may be a building management system in a building, a central station configured to monitor a plurality of handheld fire extinguishers 10, a fire monitoring authority, or potentially other third party services and devices. As such, the operation device 54 can be configured to run a software application associated with the handheld fire extinguisher 10 and operate the handheld fire extinguisher 10. The controller 50 can be configured to send a signal to the operation device 54 when the battery 42 has a charge below a predetermined level. This can prompt an operator of the handheld fire extinguisher 10 to replace or recharge the battery 42. The battery level may be measured as part of the power management circuitry. When the controller 50 and the operation device 54 are wirelessly connected, Z-Wave, Zigbee, Bluetooth, Wi-Fi, and other local area wireless technology can be used to communicate, including 802.11 standards and 802.15 standards. In other embodiments, the controller 50 may communicate over a wide area wireless network such as a cellular communications network or a fixed wire network. The handheld fire extinguisher 10 can also be in wired and/or wireless communication with a network of other handheld fire extinguishers. The operation device 54 may in turn also be equipped with wireless communications capabilities to communicate with a building management system or to alert an appropriate fire monitoring authority. The controller 50 can also be configured to send alarms and status signals to the operation device 54 indicative of other conditions within the handheld fire extinguisher 10.

The suppressant level may be measured by a variety of means. One method involves resetting a time counter when the suppressant is filled. Then the amount of time the EFFE has been activated may be measured, keeping a log of the total time the EFFE has been activated and triggering an alert when the accumulated time exceeds a set threshold. Another method involves measuring the amount of suppressant in the EFFE based on a variety of sensors that measure the volume of suppressant, weight of suppressant, or the flow of suppressant supplied to the nozzle(s). In another embodiment, the wall mount may be equipped with a weight monitor, which may measure the overall weight of the EFFE including the suppressant. As the suppressant is consumed, the overall weight of the EFFE may decrease and thus provide a means of determining when the suppressant has been consumed and requires replenishment. Another sensor may perform suppressant leak detection.

A wall mount sensor may monitor when the EFFE is dismounted from a wall and when it is taken off the wall. The sensor may be a switch, a pressure sensor, an infra-red distance sensor, or other sensor. The location of the EFFE may also be monitored to ensure it is mounted in its designated location, or if not, then the place where the EFFE may be found.

When the EFFE is taken off its mount, the usage and handling of the EFFE may be monitored and parameters, such as length of time activated, readings from fusion sensors, etc., logged and analyzed to ensure that it has not been misused or tampered with. A sensor may monitor and report the activation state of the EFFE.

Sensor fusion using such sensors as an accelerometer, magnetometer, gyroscope, camera, wireless signals, or other sensors, may be used to detect location, speed, compass direction, and acceleration and analyze the readings for movement of the EFFE and then log readings. In an alternative use of the sensors, any impact to the EFFE or if it is dropped or mis-handled may be detected, logged, and reported.

The EFFE may have an audio-visual interface for receiving commands and for providing information to, for example, an operator, or a person performing an inspection. Audio-visual instructions may be provided upon removal of the EFFE from its wall mount or when a button is depressed. The audio-visual instructions may provide operating instructions, monthly check instructions, annual inspection instructions etc.

An SOS signal may be sent to the remote monitoring system 54, which may be when an SOS button is depressed, through a verbal command, or some other sensory means of an SOS indication.

An alarm condition may result in sending a message to local law enforcement through monitoring of the system. In the case where there is a single person trying to fight a fire, authorities may be alerted at the touch of a button. Authorities may provide audio-visual guidance to the operator and monitor the condition of a fire through the camera attached to the EFFE.

The handheld fire extinguisher 10 can include an actuation device 58 in signal communication with controller 50, wherein actuation of the actuation device 58 is configured to cause the controller 50 to instruct the battery 42 to power the pump 30. The actuation device 58 can be a trigger, though in other embodiments the actuation device 58 can be a button, handle, or various other devices capable of manual actuation. Upon actuation of the actuation device 58 by the operator, the controller 50 can instruct the battery 42 to power the pump 30 so as to pump the fire suppressant material from the container 18 to the nozzle 38. When the operator releases the actuation device 58, the controller 50 can instruct the battery 42 to no longer power the pump 30, so as to cease pumping the fire suppressant material to the nozzle 38. The actuation device 58 can be located on a handle 62 of the housing 14, where the handle 62 can include a guard to prevent inadvertent actuation of the actuation device 58. The rate at which the pump 30 pumps the fire suppressant material can be dictated by the pressure with which the operator actuates the actuation device 58.

The handheld fire extinguisher 10 can include a signal device 66 in signal communication with the controller 50, where the signal device 66 is configured to produce a signal when the pump 30 is pumping the fire suppressant material to the nozzle 38. The signal device 66 may be configured to produce a signal indicative of, for example, the level of fire suppressant material within the container 18 and other conditions. Additionally, the signal device 66 can be configured to produce a signal when the battery 42 has a charge below a predetermined level. Further, the signal device 66 can produce a signal when an aspect of the controller 50, such as the software stored thereon, requires an update. The signal device 66 can be an LED, and as such the signal can be a patterned blinking light, scrolling text, etc. The signal device 66 can also produce a signal when an inspection time for the handheld fire extinguisher has become due, for instance yearly or monthly. The signal device 66 can have the functionality of a built-in flashlight for use during power outages and nighttime firefighting or other nighttime operations. The signal device 66 in other embodiments can be a piezoelectric device configured to produce an audial signal.

In operation, a condition that dictates use of a handheld fire suppressant can be detected by an operator. Once a fire is detected, the operator can hold the handheld fire extinguisher 10 and actuate the actuation device 58, which activates a relay completing a circuit in the controller 50, which activates the battery 42 to power the pump 30. The pump 30 pumps the fire suppressant material from the container 18 and through the nozzle 38 to extinguish the fire. During operation, the controller 50 can track and/or store an audit trail comprising aspects of operation of the handheld fire extinguisher 10.

The handheld fire extinguisher 10 can also include a sensor 70 in signal communication with the controller 50, where the controller 50 is configured to instruct the battery 42 to power the pump 30 when the sensor 70 detects a condition indicative of a fire. In one embodiment, the condition can be a sound produced by a fire alarm. The sensor 70 can be a single sensor or can be multiple sensors of the same type. This can be a collection of sensors 70 with different threshold or transducer characteristics measuring the same attributes or different attributes. Such attributes can comprise different or similar set of physical, chemical, or environmental attributes. The measurements performed by the sensors 70 can be used instantaneously (raw data), filtered (cleaned to remove false negatives), or matched against know pattern (in one embodiment, an acoustic sensor recognizes the sound pattern of a fire alarm for instance). If the fire alarm is triggered, the state of the handheld fire extinguisher 10 might be changed. Additionally, third party sensors, such as fire or smoke alarms, can be in signal communication with the controller 50 so as to actuate the handheld fire extinguisher 10. Further, in one embodiment the sensor 70 can be a temperature sensor.

A further component of the handheld fire extinguisher 10 can be a camera 74 attached to the housing 18, where the camera 74 is configured to record and store sound and video footage when the pump 30 is pumping the fire suppressant material to the nozzle 38. By using an embedded camera, filming while in operation and recording the operation of the handheld fire extinguisher 10 can be used to provide more information or validate the area of damage. Recording of operation can be used for insurance, big data analytics, machine learning based analysis, etc. Elements recorded by the camera 74, as well as the controller 50, include but are not limited to: time, location, parameters for nozzles, parameters for motor, speed, torque, temperatures, vapor content, and chemical composition detected. Information is stored locally on the controller 50 in a non-volatile memory. Information can be exchanged between the handheld fire extinguisher 10 and the operation device 54 through wireless and/or wired connections. The communications may be over short range using Z-Wave, Zigbee, Bluetooth, WiFi etc. or long range using cellular radio. Information collected, stored, and/or recorded by features of the handheld fire extinguisher 10 can also be uploaded to a cloud-based system.

Over time, similar handheld fire extinguishers can require costly and time-consuming maintenance. However, the handheld fire dispensing system 10 of the present application, through using the pump 30 powered by the battery 42, can require less frequent maintenance. Further, the controller 30 can produce alerts via the signal device 66 or send signals to the operation device 54 when maintenance is required, such as at set intervals in time or when a particular aspect of the handheld fire extinguisher requires maintenance, such as due to the battery 42 having a low charge level. Upon activation, the controller 50 can also communicate with the operation device 54 for further system level functionality. For example, to instruct the shutoff of various devices, such as a gas valve, stove, etc.

The controller 50 can have a physical or electronic unique ID number. This can allow the handheld fire extinguisher 10 to be associated with a time of install and location and allow the confirmation of required service.

It is Suggested by National Fire Protection Association (NFPA) 10 Standards and Codes for Portable Fire Extinguishers to Perform Monthly Tests and Inspections on Portable Fire Extinguishers, which Include Some of the Following Procedures:
Extinguishers are in their designated locations
Extinguishers are accessible and not blocked
Ensure wall mountings are secure
Operating instruction labels on extinguishers are accessible and legible
All seals and tamper indicators are not broken or missing and sound
Examination of the fire extinguisher for obvious physical damage, corrosion, leakage or clogged nozzle
Carrying out a visual inspection to checking the extinguisher has not been used or tampered with.
Taking a pressure gauge reading.
Removing the discharge hose to check for blockages or corrosion.
Accurately determine fire extinguisher contents by weighing
Clean the extinguisher
All fire extinguishers must have HMIS in place on label

If these inspections reveal that something may be wrong, then maintenance must be performed on the fire extinguisher. A written record of the manual inspections must be kept that records the month, year and person's initials who inspected it.

Yearly maintenance checks must be performed by a qualified technician from a professional fire protection agency and include formal examination of many of the same qualities already described and broadly categorized as:
Extinguishing agent
Mechanical parts
Expelling means
Physical condition

This examination primarily involves the external portion of fire extinguishers and will be to make sure there are no signs of deterioration, tampering, leaks, broken seals, host blockages, or illegible labels. Some types of extinguishers (such as cylinder- or cartridge-operated extinguishers) also require an annual internal examination.

These inspections can lead to a high level of cost for personnel to perform the monthly checks and maintain written records and for an external specialist firm to perform the yearly inspections. Therefore, the inventor's realized an economic benefit to automate some of the checks and to enable these inspections to be carried out more efficiently through remote interrogation with the EFFE and monitoring of reports from the fire extinguisher(s). In order to facilitate such capabilities, the EFFE status features described earlier may be implemented.

The controller 50 can include the following characteristics described in Table 1 below.

TABLE 1

| | Local Notification | Signal to | |
|---|---|---|---|
| | (piezo or voice | Central | |
| Status alerts | module) | Station | Fix |
| 24 Hour | No sound-all okay | Wireless/wired | Check Unit |
| Check In- | | communications | Onsite (Is it |
| Signal is sent to | | coded signal | there? Battery |
| Central Station | | sent to Central | Good, Wireless |
| noting unit | | Station to note | board OK, |
| working | | all is well. | receiver has |
| properly | | | power and |
| | | | functioning) |
| Off Hook (unit | When Off hook- | Wireless/wired | Physical |
| removed from | Unit On board | communications | Verification, |
| cradle) | piezo will beep | coded signal | Check to see |
| | rapid alerts or | signifying unit | if unit |
| | voice alert | off wall cradle | present, set |
| | | | properly |
| | | | on contacts |
| Battery | Battery | Wireless/wired | Replace with |
| Level Low | level/battery low | communications | new or fully |
| | piezo slow beeps | coded signal | charged battery |
| | or voice alert | signifying low | or Charge |
| | | battery voltage | Battery |
| | | level | existing |
| | | | battery to full |
| | | | charge |
| AC/battery dual | Loss of 110 Power, | Wireless/wired | Check Unit |
| powered | 3 short beeps, one | communications | (Is it |
| Models. | minute space or | coded signal to | receiving |
| Loss of 110 | voice alert | central station to | 110 power, |
| Power, AC | | alert local | Wireless |
| transformer has | | authorities to no | board OK, |
| no power to | | AC Power | repeater has |
| charge battery | | | power and |
| | | | functioning) |
| Trigger/Button | Trigger | Wireless/wired | Service is |
| Activated | activated/ | communications | needed. |
| (suppressant | deactivated | coded signal to | Battery, |
| expelled, | alert solid piezo | central station to | Suppressant |
| possible | or voice alert of | alert local | Replacement |
| fire alert) | condition | authorities to no | |
| | | AC Power | |
| Physical Reset | Check Physically, | Wireless/wired | Follow |
| Button | Suppressant Bag, | communications | installation |
| (If physical | Battery Level, | coded test | instructions |
| inspection is | Wireless board, | signal | and testing |
| needed) | If AC model | alert and place | procedures |
| | is power | for a sticker or | |
| | supply active. If | tag inside to | |
| | unit is at end of | show physical | |
| | specified lifetime. | test/inspection | |
| | Rebuild kit | was done. upon | |
| | installed | installation or | |
| | | inspection | |

The controller 50 can also include additional characteristics described in Table 2 below.

TABLE 2

| | Local Notification | | |
|---|---|---|---|
| | (piezo or voice | Signal to | |
| Status alerts | module) | Central Station | Fix |
| 5 Year | Warning to | Wireless/wired | Replace |
| supervisory | Service or replace | communications | suppressant |
| | unit as | coded signal | |
| | components are | signifying low | |
| | nearing end of | battery voltage | |
| | service life | level | |
| Suppressant low | Measures level of | Wireless/wired communications | |
| Supervisory | Suppressant level | coded signal signifying low | |
| | in bag, checks for | battery voltage level | |
| | leaks, ensures | | |
| | proper level of | | |
| | suppressant | | |
| Laser Pointer/or | Laser pointer | Initiated upon | |
| light activated on | activated/deactiv | activation | |
| trigger half pull | ated | | |
| ID Code every | Device | | |
| unit has assigned | identity/ | | |
| unique | authentication | | |
| identification | | | |
| number | | | |
| Test mode or | | | |
| silence button .. | | | |
| Hole with secret | | | |
| button you insert | | | |
| probe or spring | | | |
| loaded slide | | | |
| switch for 2 | | | |
| Minutes silence | | | |
| audible alerts to | | | |
| have option to | | | |
| keep in silent | | | |
| mode. | | | |
| Units, Batteries, | | | |
| Bags have date | | | |
| stamp shown on | | | |
| EFFE | | | |

It is contemplated that the fire suppressant material can be a liquid, foam, or powder. The fire suppressant material can be a commercially manufactured liquid that may be used full strength or mixed with water through various dilution percentages, for example at a 4% dilution, creating a fire suppressant material suitable for all classifications of fire. The fire suppressant material can also at least partially comprise a marker or specialized fluid usable as a forensic tool. One type of suppressant includes unique markers that are used to track spray patterns. One specific type of fire suppressant material that can be utilized is fire extinguishing foam (FEF) fire-fighting foam, which meets a wide range of firefighting challenges, including industrial, marine, mining, municipal, oil, petrochemical, and transportation.

The above specification, examples and data provide a complete description of the structure and use of exemplary embodiments of the invention. Although various embodiments of the invention have been described above with a certain degree of particularity, or with reference to one or more individual embodiments, those skilled in the art could make numerous alterations to the disclosed embodiments without departing from the spirit or scope of this invention. Other embodiments are therefore contemplated. It is intended that all material contained in the above description and shown in the accompanying drawings shall be interpreted as illustrative only of particular embodiments and not limiting. Changes in detail or structure may be made without departing from the basic elements of the invention as defined in the following claims.

While the descriptions provided here are for a portable handheld fire extinguisher, the embodiments may be applied to a variety of fire extinguishing devices including fire extinguishing devices for stovetops, HVAC systems, hot water heaters, etc. These devices may come in varying sizes for different applications and classes, the size of the suppressant bag and strength of the pump may vary depending on the application.

1. A handheld fire extinguisher, comprising:
a container configured to store a fire suppressant material;
a nozzle;
a pump in fluid communication with the container and the nozzle, wherein the pump is configured to pump the fire suppressant material from the container through the nozzle;
a battery configured to selectively power the pump; and
a controller in signal communication with a remote operation device, the controller being configured to send a signal to the remote operation device indicative of a condition of the handheld fire extinguisher.

2. The handheld fire extinguisher of claim 1, wherein the signal indicative of the condition of the handheld fire extinguisher comprises at least one of an operational condition of the battery, quantity of fire suppressant material available, physical condition of the handheld fire extinguisher, location of the handheld fire extinguisher, a log of the physical handling of the handheld fire extinguisher, or environmental conditions surrounding the handheld fire extinguisher.

3. The handheld fire extinguisher of claim 2, wherein the controller is further configured to send the signal to the operation device when the battery has a charge below a predetermined level.

4. The handheld fire extinguisher of claim 2, wherein the controller is further configured to receive signals from the operation device that are indicative of instructions regarding the operational condition of the battery.

5. The handheld fire extinguisher of claim 2, wherein the controller is in wireless communication with the operation device.

6. The handheld fire extinguisher of claim 1, further comprising:
an actuation device in signal communication with the controller, wherein actuation of the actuation device is configured to cause the controller to instruct the battery to power the pump.

7. The handheld fire extinguisher of claim 1, further comprising:
a housing configured to store the container therein; and
a port attached to the housing and electrically connected to the battery, wherein the battery is configured to be charged through the port.

8. The handheld fire extinguisher of claim 1, wherein the container comprises a flexible pouch.

9. The handheld fire extinguisher of claim 1, wherein the nozzle is adjustable so as to produce a plurality of spray patterns of the fire suppressant material.

10. The handheld fire extinguisher of claim 1, further comprising:
a signal device in signal communication with the controller, wherein the signal device is configured to produce a first signal when the pump is pumping the fire suppressant material to the nozzle.

11. The handheld fire extinguisher of claim 10, wherein the signal device is configured to produce a second signal when the battery has a charge below a predetermined level.

12. The handheld fire extinguisher of claim 1, further comprising:
a camera attached to the extinguisher, wherein the camera is configured to record when the pump is pumping the fire suppressant material to the nozzle.

13. The handheld fire extinguisher of claim 1, further comprising:
a sensor in signal communication with the controller, wherein the controller is configured to instruct the battery to power the pump when the sensor detects a condition indicative of a fire.

14. The handheld fire extinguisher of claim 13, wherein the condition comprises a sound produced by a fire alarm.

15. The handheld fire extinguisher of claim 1, wherein the fire suppressant material comprises at least one of a liquid, foam, powder, and a forensic marker.

16. A handheld fire extinguisher, comprising:
a pump configured to pump fire suppressant material from a container through a nozzle;
a battery configured to selectively power the pump; and
a controller in signal communication with the battery and a remote operation device, the controller being configured to send a signal to the operation device that is indicative of an operational condition of the handheld fire extinguisher.

17. The handheld fire extinguisher of claim 16, wherein the operational condition is at least one of a battery charge level, a level of fire suppressant in the container, a loss of power to charge the battery, a status of whether the pump is activated, and whether maintenance is required.

18. The handheld fire extinguisher of claim 16, further comprising:
a signal device in signal communication with the controller, the signal device being configured to produce a signal when the battery has a charge below a predetermined level.

19. The handheld fire extinguisher of claim 18, wherein the signal device is further configured to produce a signal indicative of the operational condition of the handheld fire extinguisher.

20. The handheld fire extinguisher of claim 16, wherein the controller is further configured to receive signals from the operation device to control at least one of an operation of the battery and an operation of the pump.
